(19) United States
(12) Patent Application Publication
(10) Pub. No.: US 2012/0043113 A1
(43) Pub. Date: Feb. 23, 2012

(54) PRINTED CIRCUIT BOARD

(75) Inventor: HUNG-YI CHIEN, Tu-Cheng (TW)

(73) Assignee: HON HAI PRECISION INDUSTRY CO., LTD., Tu-Cheng (TW)

(21) Appl. No.: 12/953,495

(22) Filed: Nov. 24, 2010

(30) Foreign Application Priority Data
Aug. 17, 2010 (TW) 99127495

(51) Int. Cl. H05K 1/00

(52) U.S. Cl. 174/250

(57) ABSTRACT

A printed circuit board (PCB) includes a ground layer, a number of conductive mount holes extending through the PCB, and a number of electromagnetic wave absorption elements located on a top surface of the PCB and aligning with corresponding mount holes. Each mount hole is lined with a conductive material to electrically connect to the ground layer. Each electromagnetic wave absorption element includes an absorption layer to absorb high-frequency noise, and a conductive layer sandwiched between the absorption layer and the top surface of the PCB, and electrically connected to a corresponding mount hole. Each conductive layer is electrically connected to the ground layer though the conductive material of the corresponding mount hole. High-frequency noise of the PCB flows into the conductive layers through the ground layer and the conductive material of the mount holes, and is absorbed by the absorption layers.

### BACKGROUND

1. Technical Field

The present disclosure relates to a printed circuit board (PCB).

2. Description of Related Art

Generally, a PCB is mounted to a chassis of an electronic device, such as a computer, with screws. The PCB includes a number of mount holes electrically connected to ground layers of the PCB. Two ends of each mount hole are connected to two tin rings located on a top surface and a bottom surface of the PCB respectively. When screws are engaged in corresponding screw holes of the chassis through the mount holes, the PCB is electrically connected to the chassis by the screws, the tin rings, and the mount holes, to be grounded through the chassis. Therefore, most electrical noise of the PCB will flow into ground through the chassis, and electromagnetic radiation of the PCB caused by the noise will be decreased. However, the chassis functions as an antenna for high frequency noise caused by imperfect layout of the PCB. Once flowing into the chassis, the high frequency noise will be radiated out of the chassis in the form of electromagnetic wave.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is a schematic diagram of a printed circuit board (PCB) in accordance with an embodiment.

FIG. 2 is a schematic diagram of the PCB of FIG. 1 assembled in a chassis of an electronic device.

FIG. 3 is a partially exploded view of the PCB and the chassis of FIG. 2.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

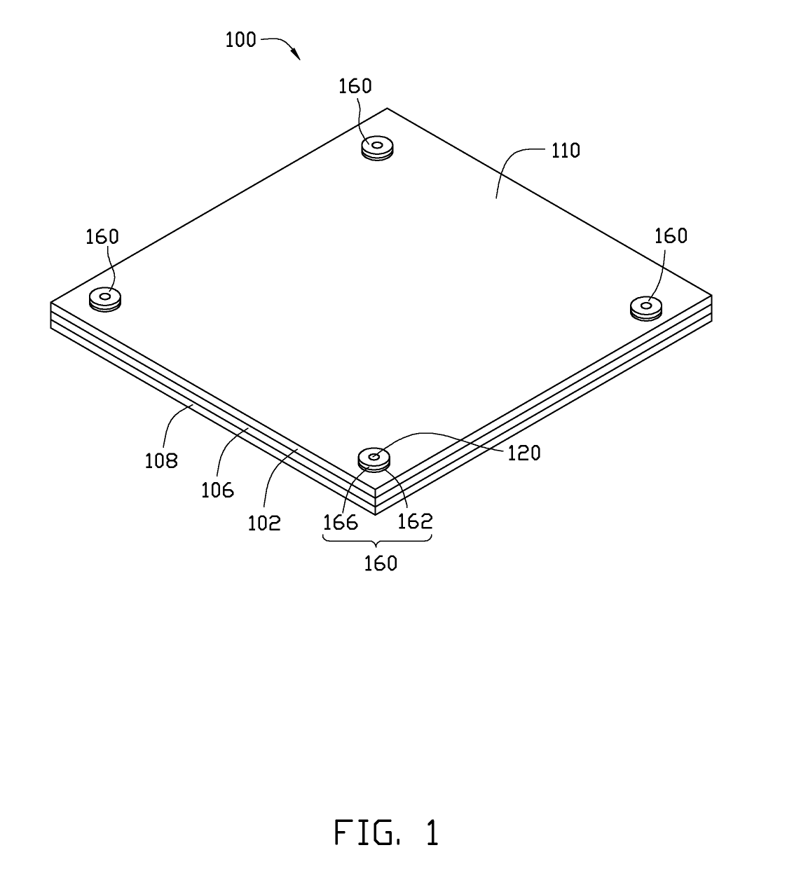

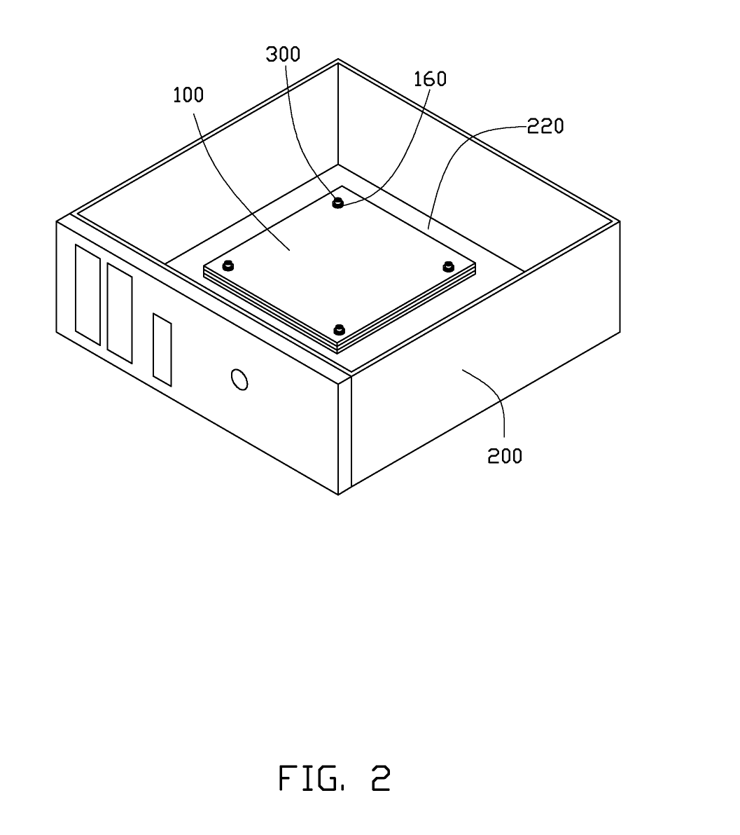

Referring to FIGS. 1 and 2, an embodiment of a printed circuit board (PCB) 100 may be assembled in a chassis 220 of an electronic device 200. The PCB 100 includes a first signal layer 102, a second signal layer 108, and a ground layer 106 sandwiched between the first signal layer 102 and the second signal layer 108. A number of conductive mount holes 120 extend through the PCB 100, and each mount hole 120 is lined with a conductive material to electrically connect to the ground layer 106. A number of circular electromagnetic wave absorption elements 160 are located on a top surface 110 of the PCB 100 and align with corresponding mount holes 120. Each electromagnetic wave absorption element 160 is electrically connected to and around a corresponding mount hole 120. It may be understood that the PCB 100 also includes other layers, such as a power layer, for example. These other layers fall within well-known technologies, and are therefore not described here.

Each electromagnetic wave absorption element 160 includes a conductive layer 162 electrically connected to a corresponding mount hole 120, and an absorption layer 166 for absorption high-frequency noise, and sandwiching the conductive layer 162 with the top surface 110 of the PCB 100. The conductive layer 162 of each electromagnetic wave absorption element 160 is electrically connected to the ground layer 106 through the conductive material of the corresponding mount hole 120. At a bottom surface of the PCB 100, and around each mount hole 120, a tin ring (not shown) is set. Each tin ring is electrically connected to a corresponding mount hole 120, and is electrically connected to the ground layer 106 through the conductive material of the corresponding mount hole 120. It may be understood that noise of the PCB 100 flows into the ground layer 106. In one embodiment, a frequency of the high-frequency noise is more than 1 gigahertz (GHz). Each electromagnetic wave absorption element 160 is ring-shaped, and outer radius and inner radius of each electromagnetic wave absorption element 160 are about 10 millimeters (mm) and 5 mm respectively. In other embodiments, the shape, the outer radius, and the inner radius of each electromagnetic wave absorption element 160 can be adjusted according to actual need.

The conductive layer 162 of each electromagnetic wave absorption element 160 is made of conductive material. The absorption layer 166 of each electromagnetic wave absorption element 160 is made of electromagnetic wave absorption material. The electromagnetic wave absorption material includes polymer medium and magnetic loss absorption material. Weight of the polymer medium accounts for the total weight of the electromagnetic wave absorption material in a range from about 5% to about 15%, and weight of the magnetic loss absorption material accounts for the total weight of the electromagnetic wave absorption material in a range from about 85% to about 95%. In one embodiment, the conductive material may be tin or copper. The electromagnetic wave absorption material is insulated. The polymer medium is chlorinated polyethylene, the magnetic loss absorption material is a mixture including iron, aluminum, and silicon. In other embodiments, proportion and ingredient of the polymer medium and the electromagnetic wave absorption material in the electromagnetic wave absorption material can be adjusted according to actual need.

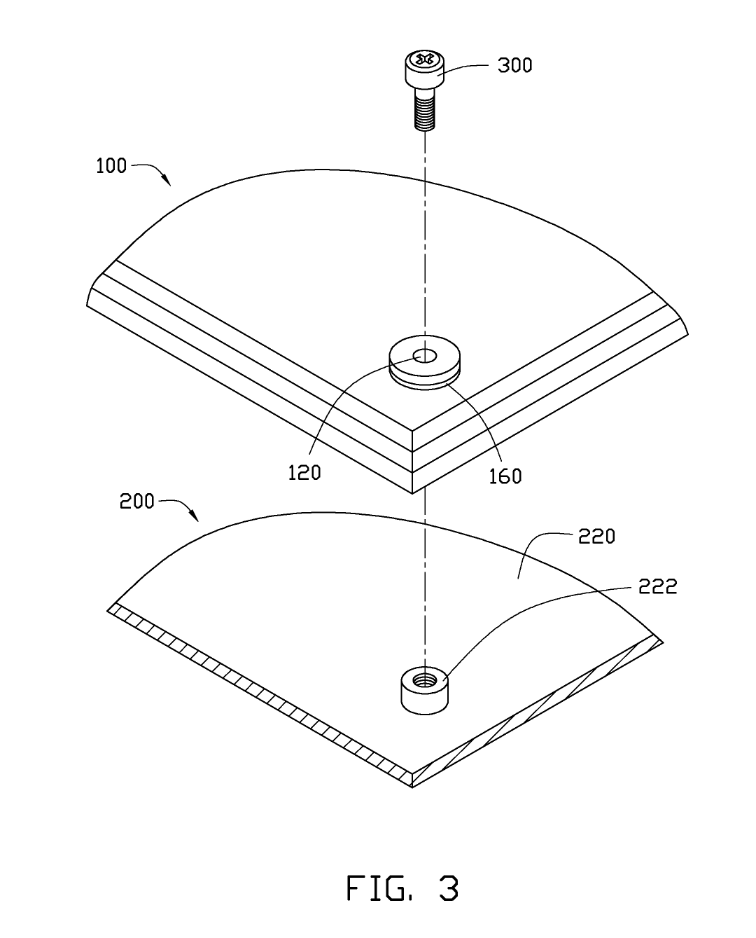

Referring to FIGS. 2 and 3, a number of conductive posts 222 defining screw holes (not labeled) are formed on the chassis 220 of the electronic device 200, corresponding to the mount holes 120. In assembly, a number of screws 300 are employed to mount the PCB 100 to the chassis 220. In detail, each screw 300 extends through a corresponding mount hole 120 from the top surface 110 of the PCB 100, and is engaged in the screw hole of a corresponding post 222. Each tin ring, at the bottom surface of the PCB 100, contacts a corresponding post 222. In one embodiment, the electronic device 200 may be a computer or a server.

In use, noise of the PCB 100 with frequency no more than 1 GHz, flows to ground through the ground layer 106, the conductive material of the mount holes 120, the tin rings, the posts 222, and the chassis 220. Noise of the PCB 100 with frequency more than 1 GHz, that is, the high-frequency noise, flows into the conductive layers 162 of the electromagnetic wave absorption elements 160 through the ground layer 106 and the conductive material of the mount holes 120, in addition, is absorbed by the absorption layers 166 of the electromagnetic wave absorption elements 160, therefore, preventing the high frequency noise from being radiated out of the chassis in the form of electromagnetic wave.

As detailed above, assembling the electromagnetic wave absorption element 160 on the top surface 110 of the PCB 100, to absorb the high-frequency noise of the PCB 100, can prevent the high frequency noise from being radiated out of the chassis in the form of electromagnetic wave. Therefore, function of the electronic device 200 to prevent electromagnetic radiation is improved.

It is to be understood, however, that even though numerous characteristics and advantages of the embodiments have been set forth in the foregoing description, together with details of the structure and function of the embodiments, the disclosure is illustrative only, and changes may be made in details, especially in matters of shape, size, and arrangement of parts within the principles of the embodiments to the full extent indicated by the broad general meaning of the terms in which the appended claims are expressed.

What is claimed is:

1. A printed circuit board (PCB) comprising:
a ground layer;
a plurality of conductive mount holes extending through the PCB, each mount hole lined with a conductive material to electrically connect to the ground layer; and
a plurality of electromagnetic wave absorption elements located on a top surface of the PCB and aligning with corresponding mount holes, each electromagnetic wave absorption element connected to and around a corresponding mount hole, wherein each electromagnetic wave absorption element comprises:
an absorption layer to absorb high-frequency noise; and
a conductive layer sandwiched between the absorption layer and the top surface of the PCB, and electrically connected to a corresponding mount hole;
wherein each conductive layer is electrically connected to the ground layer though the conductive material of the corresponding mount hole; and
wherein high-frequency noise of the PCB flows into the conductive layers through the ground layer and the conductive material of the mount holes, and is absorbed by the absorption layers.

2. The PCB of claim 1, wherein the conductive layer of each electromagnetic wave absorption element is made of conductive material, the absorption layer of each electromagnetic wave absorption element is made of electromagnetic wave absorption material.

3. The PCB of claim 2, wherein the electromagnetic wave absorption material includes polymer medium and magnetic loss absorption material.

4. The PCB of claim 3, wherein weight of the polymer medium accounts for the total weight of the electromagnetic wave absorption material in a range from about 5% to about 15%, and weight of the magnetic loss absorption material accounts for the total weight of the electromagnetic wave absorption material in a range from about 85% to about 95%.

5. The PCB of claim 3, wherein the polymer medium is chlorinated polyethylene, the magnetic loss absorption material is a mixture including iron, aluminum, and silicon.

6. The PCB of claim 1, wherein each electromagnetic wave absorption element is ring-shaped; outer radius of each electromagnetic wave absorption element is about 10 millimeters (mm), and inner radius of each electromagnetic wave absorption element is about 5 mm.
